(19) United States
(12) Patent Application Publication
(10) Pub. No.: US 2007/0274038 A1
(43) Pub. Date: Nov. 29, 2007

(54) HEAT DISSIPATING DEVICE

(75) Inventor: ZHENG-HENG SUN, Tu-Cheng (TW)

Correspondence Address: PCE INDUSTRY, INC.;ATT. CHENG-JU CHIANG JEFFREY T. KNAPP, 458 E. LAMBERT ROAD, FULLERTON, CA, 92835, US

(73) Assignee: HON HAI PRECISION INDUSTRY CO., LTD., Taipei Hsien (TW)

(21) Appl. No.: 11/309,774

(22) Filed: Sep. 22, 2006

(30) Foreign Application Priority Data
May 24, 2006 (CN) 200620014004.6

(51) Int. Cl. H05K 7/20

(52) U.S. Cl. 361/695

(57) ABSTRACT

A heat dissipating device includes a heat sink, and an air guide member. The heat sink includes a base, and a plurality of fins formed on a top surface of the base. The air guide member is detachably mounted to a side facing an airflow-generating source of the base. The air guide member includes an air guide plane which guides a part of airflow of the airflow-generating source originally flowing toward the side of the base to pass through the fins.

### FIELD OF THE INVENTION

The invention relates to heat dissipating devices, and particularly to a heat dissipating device having high heat dissipation efficiency.

### DESCRIPTION OF RELATED ART

During operation of a computer, electronic components, such as central processing units (CPUs), frequently generate large amounts of heat, therefore heat sinks are desired to dissipate heat from the electronic components.

Referring to FIG. 1, a conventional heat sink 10 includes a base 12, and a plurality of spaced fins 14 formed on a top surface of the base 12. The heat sink 10 is attached to an electronic component 18 mounted on a motherboard 16, with a bottom surface of the base 12 contacting a top surface of the electronic component 18. A fan (not shown) is set, to assist in heat dissipation, at one side of the heat sink 10 with a certain distance from the heat sink 10.

Referring to FIG. 2, airflow from the fan includes a first airflow for passing through the fins 14, and a second airflow flowing toward a side of the base 12. Because the side of the base 12 is approximately vertical to the second airflow, resistance of the second airflow is much greater and the second airflow is easy to be rebounded to generate vortexes, thereby reducing heat dissipation of the heat sink 10.

What is needed is a heat dissipating device which provides high efficiency of heat dissipation.

### SUMMARY OF THE INVENTION

An exemplary heat dissipating device includes a heat sink, and an air guide member. The heat sink includes a base, and a plurality of fins formed on a top surface of the base. The air guide member is detachably mounted to a side facing an airflow-generating source of the base. The air guide member includes an air guide plane, which guides a part of airflow of the airflow-generating source originally flowing toward the side of the base to pass through the fins.

Other advantages and novel features will become more apparent from the following detailed description when taken in conjunction with the accompanying drawing, in which:

### BRIEF DESCRIPTION OF THE DRAWINGS

FIG. 1 is a front view of a conventional heat sink, together with a motherboard and an electronic component on the motherboard;

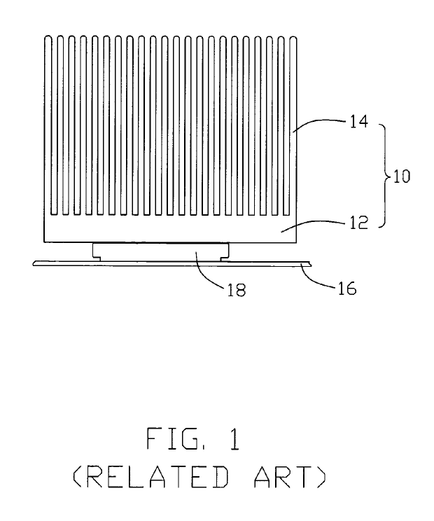

FIG. 2 is a right side view of FIG. 1;

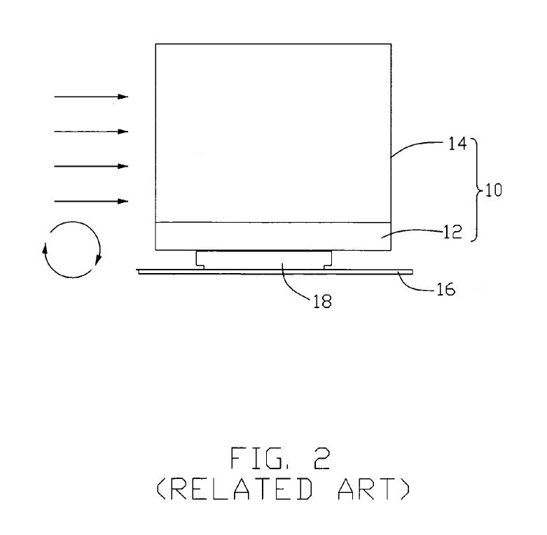

FIG. 3 is an exploded, isometric view of a heat dissipating device in accordance with a first preferred embodiment of the present invention, together with a portion of a motherboard;

FIG. 4 is an assembled view of FIG. 3;

FIG. 5 is a cross-sectional view of FIG. 4, together with a fan and a fan duct;

FIG. 6 is an exploded, isometric view of a heat dissipating device in accordance with a second preferred embodiment of the present invention, together with a motherboard; and

FIG. 7 is an assembled view of FIG. 5.

### DETAILED DESCRIPTION OF THE INVENTION

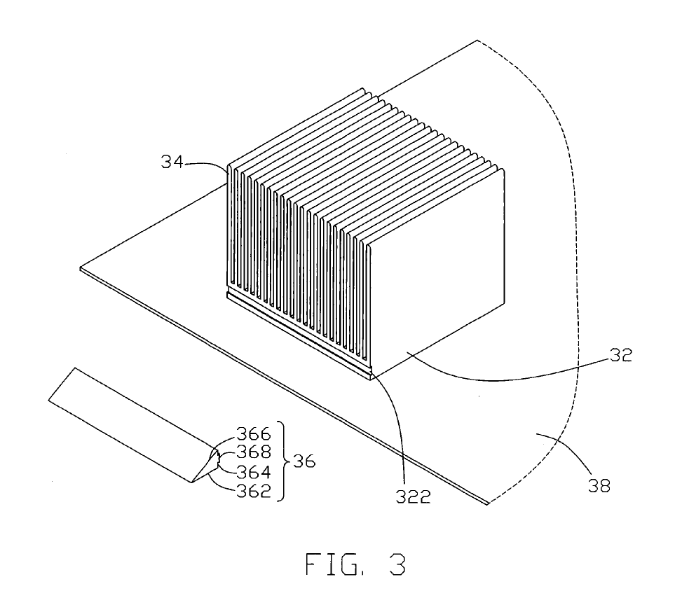

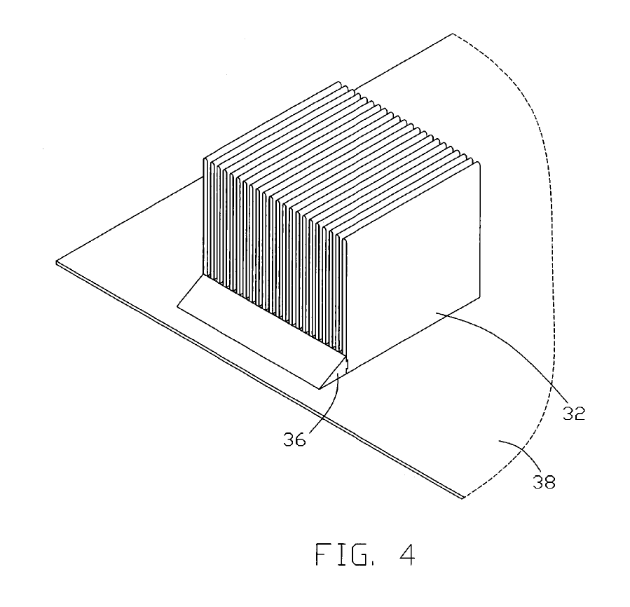

Referring to FIGS. 3 and 4, a heat dissipating device in accordance with a first preferred embodiment of the present invention includes a heat sink, and an air guide member 36.

The heat sink includes a base 32, and a plurality of spaced fins 34 formed on a top surface of the base 32.

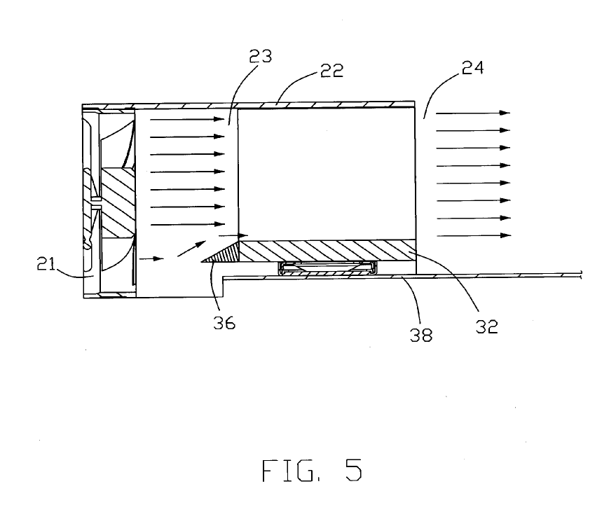

The air guide member 36 having a triangular cross section, includes a horizontal plane 362, a vertical plane 364 located at a side of the horizontal plane 362, and an air guide plane 366 connecting the other side of the horizontal plane 362 and the vertical plane 364. The air guide plane 366 is an inclined plane or a cambered plane, which is configured according to practical requirements. The air guide member 36 is mounted to a side of the base 32 facing an airflow-generating source such as a fan 21 (see FIG. 5).

A dovetail groove 322 is defined in the side of the base 32. A latching portion 368 protrudes outward from the vertical plane 364 of the air guide member 36, corresponding to the dovetail groove 322 of the base 32.

In assembly, the air guide member 36 is engaged in the dovetail groove 322 from an end thereof to mount the air guide member 36 to the base 32. The heat dissipating device is mounted on an electronic component (not shown) of a motherboard 38 for dissipating heat.

Referring also to FIG. 5, the heat dissipating device further includes a fan 21 and a fan duct 22. The fan duct 22 is mounted on the motherboard 38 and the fan 21 is mounted in the fan duct 22 at one end thereof and the heat sink is mounted in the fan duct 22 at an opposite end thereof. The air guide member 36 is located between the fan 21 and the heat sink 21. A passage being formed between the fins 34 and having an inlet 23 for receiving an airflow from the fan 21 to pass through the passage and an outlet 24 for the airflow to exit.

In the above described heat dissipating device, the fan 21 is placed near and focused at the heat sink for providing an airflow to flow through the heat sink for maximal heat dissipation. The air guide plane 366 of the air guide member 36 is capable of guiding a part of the airflow originally flowing toward the side of the base 32 to pass through the fins 34 to thereby reduce resistance to the airflow from the base 32 as compared with conventional heat sink without an air guide plane. The air guide plane 366 of the air guide member 36 reduces vortexes, which were originally produced by the airflow flowing toward the side of the base 32. Thus an airflow passing through the fins 34 is increased, which increases heat dissipation of the heat sink.

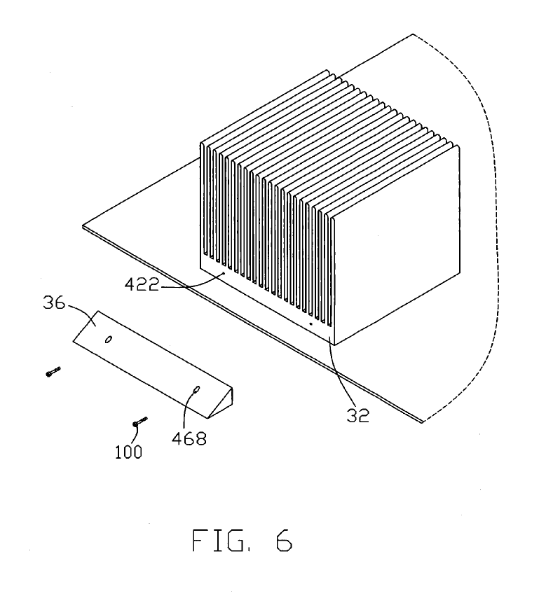

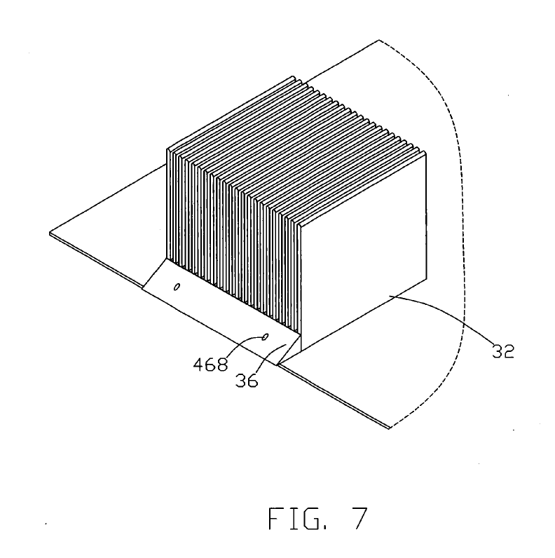

Referring also to FIGS. 6 and 7, a heat dissipating device in accordance with a second preferred embodiment of the present invention is shown. The heat dissipating device has a similar configuration to the first preferred embodiment with just a change in fixing means. Two locking holes 422 are defined in the side of the base 32. Two through holes 468 are defined in the air guide member 36 corresponding to the locking holes 422 of the base 32.

In assembly, the air guide member 36 is mounted to the base 32 by fasteners, such as two screws 100, extending through the corresponding through holes 468 of the air guide member 36, to engage in the corresponding locking holes 422 of the base 32.

Alternatively, the heat dissipating device can also be used in other occasions without using of the fan duct. The air guide member 36 can be integrally formed with the base 32.

It is to be understood, however, that even though numerous characteristics and advantages of the preferred embodiments have been set forth in the foregoing description, together with details of the structures and functions of the embodiments, the disclosure is illustrative only, and changes may be made in detail, especially in matters of shape, size, equivalent material and arrangement of parts within the principles of the invention to the full extent indicated by the broad general meaning of the terms in which the appended claims are expressed.

What is claimed is:

1. A heat dissipating device comprising:
a heat sink comprising a base, and a plurality of fins formed on a top surface of the base; and
an air guide member detachably mounted to a side of the base facing an airflow-generating source which is configured for generating an airflow to flow to the heat sink, the air guide member comprising an air guide plane which guides a part of the airflow originally flowing toward the side of the base to pass through the fins.

2. The heat dissipating device as claimed in claim 1, wherein the air guide plane is an inclined plane.

3. The heat dissipating device as claimed in claim 1, wherein the air guide plane is a cambered plane.

4. The heat dissipating device as claimed in claim 1, wherein the air guide member further comprises a horizontal plane, a vertical plane located at a side of the horizontal plane, and the air guide plane connecting the other side of the horizontal plane and the vertical plane.

5. The heat dissipating device as claimed in claim 4, wherein a dovetail groove is defined in the side of the base, a latching portion protrudes outward from the vertical plane of the air guide member to engage in the dovetail groove of the base.

6. The heat dissipating device as claimed in claim 4, wherein two locking holes are defined in the side of the base, two through holes are defined in the air guide member, two fasteners are inserted through the corresponding through holes to engage in the corresponding locking holes.

7. A heat dissipating device comprising:
a heat sink comprising a base, and a plurality of fins formed on a top surface of the base; and
an air guide member comprising an air guide plane detachably mounted to a side of the base facing an airflow-generating source which is configured for generating an airflow to flow to the heat sink, wherein resistance of the airflow from the base is minimized by the air guide plane.

8. The heat dissipating device as claimed in claim 7, wherein the air guide plane is an inclined plane.

9. The heat dissipating device as claimed in claim 7, wherein the air guide plane is a cambered plane.

10. The heat dissipating device as claimed in claim 7, wherein the air guide member further comprises a horizontal plane, a vertical plane located at a side of the horizontal plane, and the air guide plane connecting the other side of the horizontal plane and the vertical plane.

11. The heat dissipating device as claimed in claim 10, wherein a dovetail groove is defined in the side of the base, a latching portion protrudes outward from the vertical plane of the air guide member to engage in the dovetail groove of the base.

12. The heat dissipating device as claimed in claim 10, wherein two locking holes are defined in the side of the base, two through holes are defined in the air guide member, two fasteners are inserted through the corresponding through holes to engage in the corresponding locking holes.

13. A heat dissipating device comprising:
a heat sink comprising a base, and a plurality of fins formed on a top surface of the base, a passage being formed between the fins and having an inlet for receiving an airflow to pass through the passage and an outlet for the airflow to exit; and
an air guide member provided at a side of the base adjacent to the inlet, the air guide member comprising an air guide plane configured for guiding a part of the airflow originally flowing toward the side of the base to pass through the fins.

14. The heat dissipating device as claimed in claim 13, further comprising a fan duct and a fan, wherein the fan is mounted in the fan duct at one end thereof and the heat sink is mounted in the fan duct at an opposite end thereof, the air guide member is located between the fan and the heat sink.

15. The heat dissipating device as claimed in claim 14, wherein the fan duct is mounted on a motherboard and the heat sink is mounted on an electronic component which is installed on the motherboard.

16. The heat dissipating device as claimed in claim 13, wherein the air guide member is integrally formed with the base.

17. The heat dissipating device as claimed in claim 13, wherein the air guide member is detachably attached to the base.

18. The heat dissipating device as claimed in claim 17, wherein the air guide member is attached to the base by screws.

19. The heat dissipating device as claimed in claim 17, wherein the air guide member is attached to the base by engagment between a dovetail groove and a dovetail protrusion.
